(19) United States
(12) Patent Application Publication
(10) Pub. No.: US 2009/0266400 A1
(43) Pub. Date: Oct. 29, 2009

(54) APPARATUS AND METHOD FOR ATTACHING SOLAR PANELS TO ROOF SYSTEM SURFACES

(76) Inventors: Jack P. DeLiddo, Ripon, CA (US); John Abkemeier, St. Louis, MO (US)

Correspondence Address: ORRICK, HERRINGTON & SUTCLIFFE, LLP;IP PROSECUTION DEPARTMENT, 4 PARK PLAZA, SUITE 1600, IRVINE, CA, 92614-2558, US

(21) Appl. No.: 12/191,232

(22) Filed: Aug. 13, 2008

Related U.S. Application Data
(63) Continuation-in-part of application No. 11/894,287, filed on Aug. 20, 2007.
Application No. 11/894,287 is a continuation-in-part of application No. 11/784,244, filed on Apr. 5, 2007.
(60) Provisional application No. 60/414,535, filed on Apr. 22, 2006.

(51) Int. Cl. H01L 31/042; A47B 96/06; A44B 18/00

(52) U.S. Cl. 136/244; 248/205.2

(57) ABSTRACT

An apparatus and method for attaching photovoltaic solar panels to a roof system surface. Thin film flexible panels are attached using a hook and loop system in which either the hook or loop material is attached to the underside of panel, and the other of the hook and loop material is attached the roof. Solar panels that are encased in a frame are attached using the hook and loop material directly to the roof system structure, or to an intermediate structure, which is in turn attached to the roof system surface. The method also determines the amount of mated hook and loop material that must be attached to each installed panel to ensure that the installed panels will be able to withstand the wind pressure uplift force required, and to ensure that in the event unexpected and excessive uplift force is ever encountered, the panels separate at the hook and loop interface. For roof system surfaces using a multiple layer membrane material, the hook or loop material can be directly attached to the membrane during its manufacturing process to eliminate the need of doing so at the job site. In other embodiments, the solar panel is attached first to an elongate tray-like structure that is then attached to a roof, and in yet another embodiment, the solar panel is attached by means of adhesive or hook and loop material to the upper surface of a roofing membrane, which is then attached to the roof surface.

### REFERENCE TO CO-PENDING APPLICATION

This application is a continuation-in-part of application Ser. No. 11/894,287, filed on Aug. 20, 2007, now pending, which is a continuation-in-part of application Ser. No. 11/784,244, filed on Apr. 5, 2007, now pending, which claims the benefit of Provisional Application No. 60/414,535, filed on Apr. 22, 2006, all of which are incorporated herein fully by reference.

### FIELD OF THE INVENTION

The invention pertains generally to a mechanical device and method for attaching solar panels (that is, photovoltaic panels), or a series of panels, to the surface of a roof. In particular, this invention pertains to apparatus and methods for attaching thin film and framed solar panels in a way that can be readily installed on and removed from a variety of different type roof surfaces, is durable, lightweight, accommodates the various weather conditions encountered by such systems, including the differing coefficients of thermal expansion between whatever the roof material upon which the panels are installed and the panels themselves, is attractive, and is cost effective.

### BACKGROUND OF THE INVENTION

With the increasing cost and demand for energy in all forms and in all applications, alternative sources for energy continue to be sought and utilized. One example of this is the commercial and residential use of solar energy. Particularly in the commercial arena, designers, developers and owners of large commercial buildings are increasingly considering alternative sources of core and/or supplemental energy rather than face the certainty of price increases and the uncertainties of availability in the future. Indeed, some commercial users intend to provide electricity generation not only for their own on-site consumption, but also for sale of power to the local community utility companies.

One of the most popular means for on-site power generation is solar power. The use of solar power is of course not new. The harnessing and use of solar power by mankind probably dates back to the 7^{th} Century B.C., when magnifying glasses were used to focus light on a fuel to light a fire for light, warmth and cooking. It is reported that in the 2^{nd} Century B.C., the Greek scientist Archimedes used focused and reflected sunlight to set attacking Roman ships afire.

A popular solar-powered, electrical generation device is the photovoltaic system that converts light into electricity. The basic light-to-electricity phenomenon (sometimes referred to as the photovoltaic or PV effect) was first discovered in 1839. But it took nearly another century before scientists truly understood this process, and it was discovered that the conversion process occurs at the atomic level. During that time, many renowned scientists became interested in the PV effect. Even Albert Einstein published a paper on it in 1905.

The actual birth date for modern photovoltaic technology is traced back to 1954, when scientists Chaplin, Fuller and Pearson, all at Bell Labs, developed the silicon photovoltaic cell—which was the first solar cell that was capable of generating enough power to run common electrical equipment. Interestingly, solar-powered dollar bill changers were among the first products to be solar powered. Perhaps the most significant early utilizations of PV cells were on satellites. In 1958, a small PV array was used on the Vanguard I space satellite to power its radios. Later that same year, satellites Explorer III, Vanguard II and Sputnik-3 all included PV-powered systems onboard. The efficacy and reliability of PV was now established, and by the next decade, selenium and silicon cells were being commercially produced and sold.

In 1972, the University of Delaware established the Institute for Energy Conversion to do research on and development of thin-film photovoltaic and solar thermal systems, and that Institute built a PV/thermal hybrid system that used roof-integrated arrays to feed power through a special meter to the local utility company during the day, and then lower-cost power was purchased during the sun-less night. The roof-integrated PV system had been borne.

Not long thereafter, the energy crisis, with its long lines at the gas pump and spiking gas prices, fanned the public interest in non-fossil fuels, and solar power was at the top of the list. So much so that the U.S. Government launched the Solar Energy Research Institute as part of the Department of Energy. And interest in photovoltaic systems, which were already being used in many commercial applications, became similarly attenuated. That interest has essentially continued unabated since.

Therefore, for over thirty years, it has been know that photovoltaic products, including thin film products, could be attached to the roof of buildings in order to generate electricity. And in that time, an entire industry has evolved that is devoted to that very thing, and that industry has, over that time, developed a number of methods for attaching the panels to a roof. Many of the systems have involved mechanically attaching the panels directly to the roof system surface using, for example, bolts or screws or other similar devices. Of course, these systems inherently involved drilling holes into the roof system surface or otherwise disturbing the integrity of the roof surface, particularly over time as inclement weather, wind and heat (with the differing coefficients of expansion between the panels and the roof surface) created stresses at the attachment points. This could and often did lead to compromising the water repellant properties of the roof or worse. Accordingly, attachment systems that did not puncture the existing surface were preferred. Also, for significant tax reasons, having the system not be permanently attached to the roof of the structure was often preferred. Therefore, attachment systems in which the panels were removably secured on the roof top were developed.

A commonly used system involved the panel/frame systems being simply laid on the roof material and weighed there using ballast blocks. Needless to say, building the frame and using ballast blocks to hold them down onto the roof added costs, components and weight to the system. Some existing systems may not have been initially engineered to withstand the added weight of the panels and ballast. Accordingly, the cost not only to purchase and install the panels and the ballast, but to also reinforce to roof system may have proven prohibitive. The ballast weight may need to be substantial because the solar panels, by definition, must cover a relatively large area in order to be effective. Therefore, they may be subjected to very high winds, and the ballast needs to keep the panels and support structure in place, otherwise they can become an airborne-projectile that can cause damage to people and property.

The added costs, inconvenience and weight affiliated with these ballast-type systems created the need in the industry for a better apparatus and method to attach solar panels, and particularly thin film panels, to an existing roof system.

While this development was ongoing in the field of photovoltaic panels and their use in roof-based systems, a Swiss engineer, Georges de Mestral, who had become intrigued with the way in which seeds from a particular plant that grew in the Alps so securely stuck to his clothing and to the fur of his dog after their daily summer walk, was developing the hook and loop attachment technology. In 1941, upon examining the seeds and how they became attached to his dog and himself more closely, Mr. de Mestal saw that the spherical seeds had tiny hooks on the end of their needle-like projections, and those hooks mechanically attached themselves to the fabric in his clothing and his dog's fur, from which they could be removed, but with considerable effort. He saw the possibility of using a similar arrangement to bind two materials together securely but reversibly in a simple fashion. Thus was born the now well-known hook-and-loop attachment system, which de Mestral named VELCRO®, now a registered trademark of the Velcro USA company, headquartered in Manchester, N.H. The hook-and-loop attachment system has been used for many varied applications, from all sorts of clothing as replacement for buttons and zippers, for children's shoes to replace the laces, and to many strap-like applications to replace buckles, as the hook material on one side of the strap will adhere to the loop material on the other side of the strap when it is wound upon itself.

Prior to the work on the inventions herein described, however, it is believed that no one has even attempted to apply hook-and-loop technology as an attachment mechanism for adhering solar panels to roof systems, let alone done so successfully. Indeed, the applicant is in the process of working with Velcro USA on a supply agreement for the embodiments shown herein, and the representatives at Velcro USA with whom applicant have dealt have also confirmed that they too are unaware of anyone before applicant utilizing the Velcro® hook and loop material for the applications herein described.

That hook and loop material has not previously been used in this application is not surprising. For one thing, it is extremely important that once solar panels are put into place on a roof, that they stay there. Unfortunately, by definition solar panels must be exposed to the elements, including the wind. And in certain situations and environments, the solar panels can be exposed to wind gusts up to and even in excess of 100 mph. Earthquakes can also cause the solar panels to move if not adequately secured. Because of the risk of injury to property and to persons if the solar panels move, or worse, become airborne in the wind, require that whatever method and mechanism are used to secure the panels to the roof, they must be adequate to hold the panel in place even in extreme conditions. Given these concerns, it is not surprising that using hook-and-loop technology has not previously been used, and would not be an obvious choice to use, as the means and method to attach these panels to a roof.

Utilizing the methods and apparatuses hereinafter described, a system for attaching solar panels is achieved which is lightweight (typically less than 1 pound per square foot of coverage) such that re-engineering of the existing roof system is not required; is low cost (requiring less time, personnel, hardware and equipment to install); provides for rapid electrical integration; requires no roof penetration; requires no ballast; presents no added roof obstacles beyond the panels themselves; is easily removable, if necessary, without damage to the roof system; can be applied not only to flat roof systems, but also to sloped and curved roof systems; can be easily configured to accommodate existing roof installations; and is aesthetically pleasing, among other advantages.

### SUMMARY OF THE INVENTION

The present invention uses a hook-and-loop system as the attachment means to adhere the solar panels to the roof top material, or to an intermediary structure. This can be used with either the flexible thin film solar panels, or with framed solar panels. This can be used to attach the framed panels directly to the roof surface, or to racks or other intermediate structures that are in turn attached to the roof. The hook material can be attached using any suitable means such as adhesive along the edges of the underside of the flexible thin film solar panel, and the loop material can be attached directly to the top of the roofing systems, again using any suitable means, such as adhesive, in an area that coincides with the preferred arrangement of the panels on the roof, so that the hook and loop aspects properly align and mate upon installation. In the preferred embodiment, it has been found that for ease and success of installation, the entire underside of the thin film solar panels can be fitted with either the hook or the loop material, and that the other portion can be strategically placed on the roof, thereby eliminating the need for the two portions to be exactly aligned before attachment. In another preferred embodiment, the hook material, being less expensive than the loop material, is attached to the underside of the panel, and the loop material is attached to the roof. In another preferred embodiment, the hook material is thermally bonded directly to the underside of the panel during the construction of the panel, preferably a Uni-Solar PVL-136 Panel, so as to eliminate the need for an adhesive layer between the hook material and the underside of the panel. In yet another preferred embodiment, the solar panels are first housed or adhered to steel, metal or plastic frame-like or rack-like substrate (which can have flat or corrugated underside, and then the substrates can be attached to the roof system using hook and loop. In yet another preferred embodiment, the substrate is formed into customized channels or track into which the thin film panels are inserted, and then the track is attached using hook and loop material. In the preferred method, the amount of area required for hook and loop attachment is calculated to ensure that the panels, once attached, remain in place.

In another preferred embodiment on the present invention, either the loop or hook material can be directly adhered, or imbedded into, the upper layer of a built-up roofing membrane material during its construction.

In another preferred embodiment on the present invention, rather that attaching the solar panels directly to a corrugated roof, the solar panels can be attached via adhesive or hook and loop material to the interior surface of a tray-like structure, and then the tray-like structure can be attached via adhesive or hook and loop material to the upper sections of the corrugated roof.

In yet another preferred embodiment of the present invention, the solar panel can be directly attached to the roofing membrane that is intended for application to the top of an existing or new upper roof surface; and then the membranes (with solar panels already installed), are attached to the upper roof surface using either adhesive or hook and loop material.

Utilizing this system, the panels can be attached in a way that is very cost effective, and does not add weight to the roofing system. Also, the hook and loop material will absorb some movement between the solar panels and the roof system which occurs dues to the differing coefficients of heat expansion between the two different materials. Therefore, the roofing system nor the panels will be subjected to damaging stress as the panel and the roof system are repeatedly cycled through the heat of the day and the cold of the night.

### DESCRIPTION OF THE FIGURES

FIG. 1 shows a typical attachment arrangement in which either the hook or the loop portion of a typical hook-and-loop two part attachment system is attached to the underside of the solar panel, whereas the other part of the hook-and-loop attachment system is attached directly to the upper surface of the roof. In this instance, the hook and the loop portions will interact to hold the solar panel directly to the roof.

FIG. 2 shows an alternative attachment arrangement in which the solar panel is first attached to an intermediate device, such as a frame, and then either the hook or the loop portion of a typical hook-and-loop two part attachment system is attached to the underside of the frame, whereas the other part of the hook-and-loop attachment system is attached directly to the upper surface of the roof. In this instance, the hook and the loop portions will interact to hold the framed solar panel to the roof.

FIG. 3 shows the presently preferred construct of the thin film solar panel to which the hook material is thermally bonded to the entirety of the underside of the solar panel.

FIG. 4 shows in side view a schematic of the preferred mating of the solar panel, the hook material, the loop material and the upper surface of the roof system.

FIG. 5 shows an alternative method for bonding the hook material to the underside of the panel using an intermediate double-sided adhesive.

FIG. 6 shows a side view of one embodiment in which a thin film solar panel is attached to the roof wherein the entirety of the underside of the panel is fitted with the hook material, and strips of the loop material are attached to the roof system. In this embodiment, the loop material strips are first laid out and attached to the roof, and then the hook material on the underside of the panels is attached thereto. Because the entirety of the underside of the panel is fitted with the hook material, exact precision in aligning the hook material with the loop strips is not required. The amount of the loop material required per square area of panel is calculated using the method of this invention.

FIG. 7 shows another embodiment in which the underside of the solar panel is completely fitted with a layer of double-sided adhesive to which the hook material is similarly attached, covering the entire underside of the panel. The loop strips, in an amount calculated as hereinafter described, are then attached to the edges of the panel's underside-covered hook material. Adhesive on the underside of the loop strips is then used to attach that assemblage to the roof system surface (or other intermediary structure or substrate).

FIG. 8 shows yet another embodiment in which adjacent panels, with hook material attached, can be attached to one another in a sheet-like way, and then the entire sheet attached to the loop material attached to the roof system surface.

FIG. 9 shows an alternative embodiment in which an array of framed solar panels are mechanically attached to brackets, which are in turn attached to the roof system surface using hook and loop material.

FIG. 10 shows an alternative embodiment in which the framed solar panels can be directly attached to the roof system surface by placing strips of hook material to the frame edges, which then mate with loop material attached directly to the roof system surface.

FIG. 11 shows an alternative embodiment where, due to the latitude of the building location, it is preferred that the panels not be installed flat on the roof system surface, but are at a slight angle so as to catch the sun's light more directly. In that instance, as shown in this Figure, the framed solar panels can be attached to a simple intermediate structure that can be constructed of metal or plastic or other suitable material and that when attached to the roof system, presents the solar panel at the preferred angle relative to the sun. The framed solar panel can be mechanically attached to the support structure by any suitable means, such as screws or bolts, for example, and the structure can be attached to the roof surface using hook and loop. Again, the amount of hook and loop material that must be used is calculated using the method hereinafter described.

FIG. 12 shows another embodiment that can be utilized with a pre-framed panel, in which a I-Rail or similar intermediary structure is used, to which the frame of the panel is attached to the upper portion by mechanical means such as screws or bolts, and the lower end of the I-Rail is attached to the roof system surface using hook and loop. As shown here, both the hook and loop portions are attached using a double-sided adhesive.

FIG. 13 shows another embodiment that can be utilized with a pre-framed panel that utilizes the same I-Rail or similar intermediary structure as in FIG. 13, but in which an upper pair of metal and rubber washers are used with a single screw that does not puncture the panel frame.

FIG. 14 shows an embodiment that can be utilized with the flexible panels and with the I-Rail or similar intermediary structure as in FIGS. 12 and 13, in which a metal plate is first attached to or lain on the upper surface of the I-Rail or block, and the flexible panels attached thereto by means of a clamping device, which is attached to the I-Rail by mechanical means such as screws or bolts, and the lower end of the I-rail is attached to the roof system surface using hook and loop. As shown here, both the hook and loop portions are attached using a double-sided adhesive.

FIG. 15 is another embodiment by which the flexible panels can be attached to the underlying metal plate, and then the adjacent plates attached to a single I-Rail.

FIG. 16 shows a top view of a grid lay-out in which the I-Rails are of relatively short length such that they appear to be square and are positioned only at the corners of each of the panels.

FIG. 17 is another embodiment by which the flexible panels can be attached to an underlying metal plate, but in this instance the underlying metal plate resides on a corrugated substrate structure (shown in cross-section in this Figure).

FIG. 18 shows the same embodiment as in FIG. 17, but with the additional detail showing how the substrate structure can be attached to the roof system surface using the hook and loop system.

FIG. 19 shows a typical layout of a pair of thin film solar panels, depicting their relative length and width, as they would appear in a top view after they had been installed on the roof system structure by any of the embodiments shown above, except those using the I-Rail component. The top view of those embodiments would appear substantially the same, except that the screws, clamps and washers used to attach the assemblage to the I-Rail would be visible, but only barely. As can be seen from this Figure, the resulting installation has a clean, aesthetic appearance.

FIG. 20 is a flow chart that summarizes the steps by which the amount of hook and loop material to be used in any given application is determined, and other steps in the preferred method for attachment of solar panels using hook and loop material.

FIG. 21 shows a cross-sectional view of a roofing membrane in which strips of either the hook or loop material are embedded into the upper layer of the membrane during the manufacturing process.

FIG. 22 shows an enlarged view, taken from area 22-22 in FIG. 21 that shows greater detail of the manner in which the hook or look strip is attached during the build-up manufacturing process of the membrane material.

FIG. 23 shows a top view of the completed membrane in which the strips of either the hook or loop material is embedded along the entire length of the membrane material.

FIG. 24 shows a side view of two membrane pieces in end-to-end attachment.

FIG. 25 is a perspective view showing one embodiment in which the solar panel is first attached to a tray-like structure, which is in turn attached to the upper surface of the roof structure. Here, it is shown being attached to the upper surface of a corrugated structure, but the tray-like mechanism could be used with other roofing surfaces as well.

FIG. 26 is a side view of the structure and assemblage shown in FIG. 25, and shows how the tray-like structure is attached to the upper surface of the corrugated roofing material. As shown here, the connection is by means of hook and look material, and is attached at each raised portion of the corrugate roof. For certain installations, it may be possible to use less hook and loop material.

FIG. 27 is a schematic view showing the sandwich between the upper solar panel, the adhesive (or hook and loop) center section, and the bottom of the tray-like structure.

FIG. 28 is an end view of the structure and assemblage shown in FIG. 25.

FIG. 29 is a schematic showing the sandwiching and attachment of the solar patent to the roofing membrane which is in turn attached to the upper roof surface.

### DETAILED DESCRIPTION OF THE PREFERRED EMBODIMENT

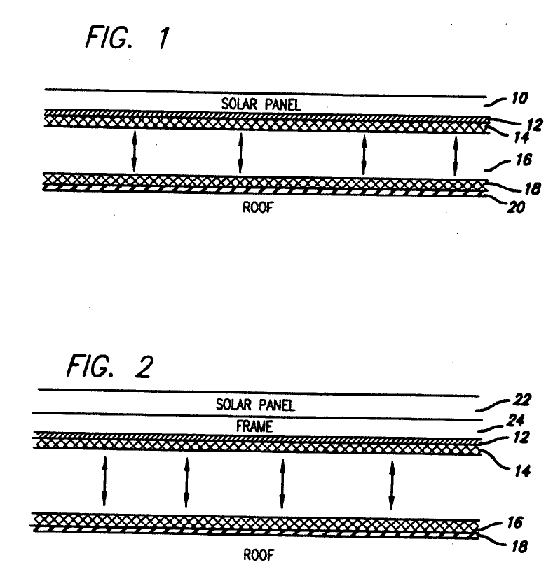

A shown in FIG. 1, the preferred attachment method utilizes a hook and loop material, such as that available from Velcro USA. The preferred material is Velcro® hook material model 752 and Velcro® loop material model 3001. In the most basic form of attachment, a solar panel 10 as shown in FIG. 1 is a thin film flexible panel, such as is available from Uni-Solar, among other suppliers. In the preferred embodiment, the panel is a Uni-Solar® panel model number PVL-136, although other types and models can be utilized. Typically, the Uni-Solar panels are commercially available in size that is approximately 216 inches long, 15.5 inches wide, and 0.12 inches thick, weighing 17 pounds. These solar panels can be ordered with an adhesive material already applied to their underside, covered by a peelable protective material.

As shown in FIG. 1, the solar panel 10 has attached to its underside with adhesive 12 to the hook material 14 of a conventional hook and loop attachment system. The hook material 16 is attached by means of an adhesive layer 18 to the roof system surface 20. Although in this embodiment, and in the various other embodiments herein discussed, disclosed and depicted, the hook material 14 is shown as being attached to the underside of the solar panel (or panel frame as the case may be), and the loop material 16 is shown as being attached to the roof system surface 20, the opposite could be done as well, with the loop material 14 attached to the underside of the panel 10 and the hook material 14 attached to the roof system surface 20. The orientation disclosed, however, is preferred in that hook material 14 is typically less expensive that loop material 16, and since in most application less material is applied to the roof system surface 20 than is applied to the panel 10, applying the hook material 14 to the panel 10 is a potential cost saving matter.

The preferred adhesive layers 12 and 18 for this embodiment is available from Sika Corporation, SikaLastomer®-68 ethylene propylene copolymer tape, as it has been found to have acceptable strength and durability, and compatibility with the material on the underside of the most commercially available flexible solar panels 10. It has also been found to be suitable for attachment to most roof system surfaces 20. Because, however, there are many different types of roof surface materials, any adhesive 18 must first be tested to confirm that it will properly adhere to and is compatible with the roof surface 20, but also care should be taken to ensure that application will not adversely affect any warranty that may then be extant for the roof system and/or surface.

The adhesive layer 18 is applied to the underside of the loop portion 16, and then that combination is applied directly to the roof surface 20. It is important, of course, to ensure that the roof surface 20 is free of contaminants or other material that would impede a good bond between the adhesive layer 18 and the surface 20. Utilizing thin film panels 10 provides a flexible, lightweight system that will find utility with most roof systems, and will be particularly useful and applicable in situations that involve curved or sloped roof systems, or where the existing roof system is not engineered to accommodate significant added weight, or where aesthetics of the roof after installation is a design criteria.

In addition to thin film flexible solar panels, also commercially available are framed solar panels 22 in which the panels are not flexible, but are typically constructed of some type of rigid material housed within a protective metal frame 24. In that circumstance, the hook material 14 can be attached using the adhesive 18 to the metal frame 24, and the mating loop material 16 attached to the roof as described above.

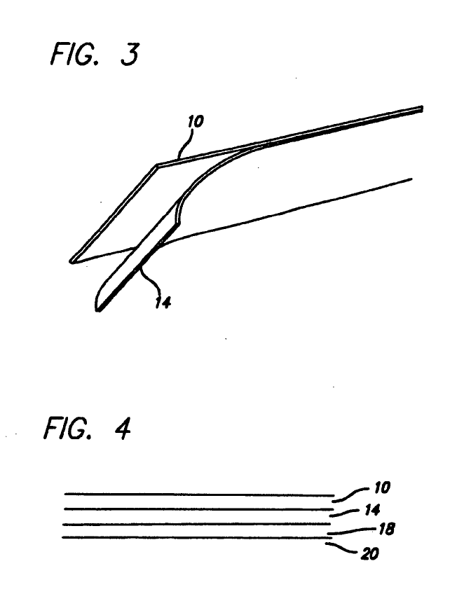

Turning to FIG. 3, the presently preferred solar panel 10 in which the hook material 14 is bonded directly to the underside of the panel 10 during or immediately after manufacture of the panel itself is shown. As shown in FIG. 3, a portion of the hook material 14 is depicted as being peeled away from the underside of the panel 10. As manufactured, however, the preferred embodiment will have the entire underside of the panel 10 covered with securely attached hook material 14, and no portion will be separated as shown in FIG. 3. The depiction in FIG. 3 is included only to emphasize that what is depicted is two similar sized components (panel 10 and material 14) that are directly bonded to one another.

Using this pre-bonded panel-and-hook-material component eliminates the need for the separate step of applying the hook material to the underside of the panel in the field, and also eliminates a separate component that must be applied in the field, such as additional adhesive material tape that can be used to attach the hook material to the underside of the panel. Also, application of the hook material 14 to the solar panel during or immediately after the manufacturing process will ensure a superior and more reliable attachment that will not be affected by conditions at the job site, or dependent upon the skill of the installer.

In this embodiment, the entire underside of the panel is affixed with hook material 14. Although for most installations, less than all of the directly-bonded hook material 14 will be mated with loop material, it is still believed that the benefits to be derived from direct-bonding outweighs any material cost saving that could realized by only applying the amount of hook material 14 actually needed at the job site.

Any of the conventional means for direct bonding of the hook material 14 to the underside of panel 10 could be used. For example and not limitation, a thermal bonding or other heat weld could be employed; or any suitable adhesive material could be used, such as a polymer adhesive of the types available from various vendors, such as Du Pont.

FIG. 4 shows schematically in side view the application sandwich using the preferred panel 10 shown in FIG. 3, with the hook material 14 having been directly bonded during or immediately after manufacture of the panel 10, which is attached to the loop material 14 which is in turn attached to the roof system surface 20 by means of adhesive layer 18.

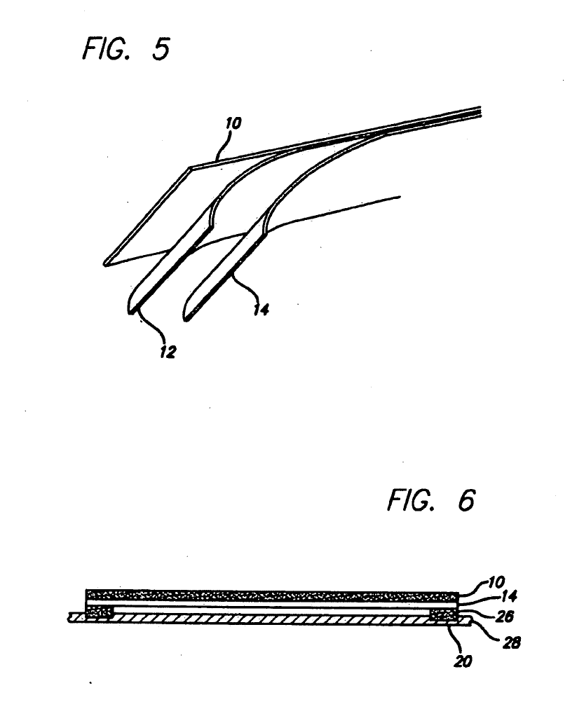

Turning to FIG. 5, another embodiment is shown in which the panel 10 is attached to the hook material 14 by means of the intermediately adhesive tape 12. As shown here, even in this embodiment, it is preferred that the entire underside of the panel 10 be fitted with the hook material 14. T his will provide a more durable adhesion between the two interfaces of panel-tape and tape-hook material as there will be greater surface area of attachment, and also fewer edge areas where initial separation can occur.

At this point, it should be noted that there are many different types of roof system surfaces 20 that may be encountered in the field. Some of the more typical surfaces to which solar panels may be attached using the means and methods discussed herein are white membrane, metal, PVC or foam. Of course, in order for the means and methods discussed here to be utilized, the roof system surface 20 must be of a type to which an adhesive will adequately adhere in terms of strength of bond, durability of bond, and lack of damage to the surface material. If the roof system surface 20 is not of such a material, then an intermediately step to coat the surface with a material that will provide such a suitable attachment material may be necessary. For example, for a foam-type roof system surface, it has been found that first applying a coating of HYDRO Bond #7 primer to the foam will create an upper surface to which the loop material 16 can be readily attached. It has also been discovered that if desired the loop material 16 can be directly embedded in the still-wet primer after it is applied, and that once attached, the loop material is adequately secured. For another example, some roof system surfaces 20 or topped with an asphalt material. It has also been discovered that the loop material 16 can be directly embedded in the asphalt material, and that too will provide a suitable attachment. Such an arrangement is graphically depicted in FIG. 6 where strips 26 of the loop material 16 are shown has having been slightly embedded in the upper coating 28 of the roof system surface 20.

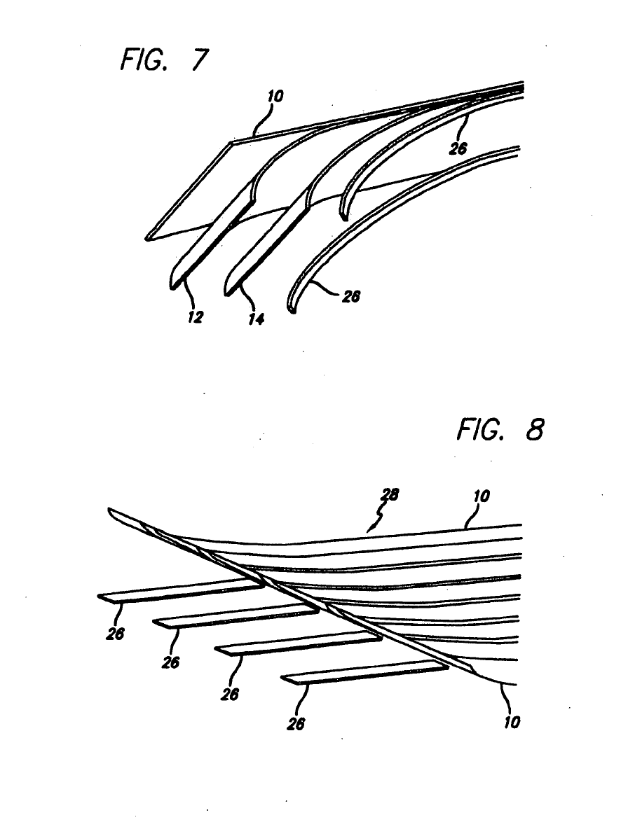

Of course, it is also possible to apply all of the various components of the sandwich—panel 10, tape 12, hook material 14 and the desired amount of the loop material 18—initially and before taking these sandwiched components to the job site. Such an arrangement is shown in FIG. 7, with the ends of the components shown separated from one another in this view for ease of understanding. In actual use, of course, all components depicted would be sandwiched together over their entire surface.

It would also be possible to assemble and join by any suitable means a number of adjacent panels 10 to create a wide array 28, as is depicted in FIG. 8. As shown there, in this installation, the individual panels 10 have had the hook material 14 pre-attached, and the strips 26 of loop material 16 have already been affixed to the roof system surface 20, either by use of an intermediate adhesive layer 18 or by directly embedding the underside of the strips 26 into a layer of material that has been applied to the surface 20.

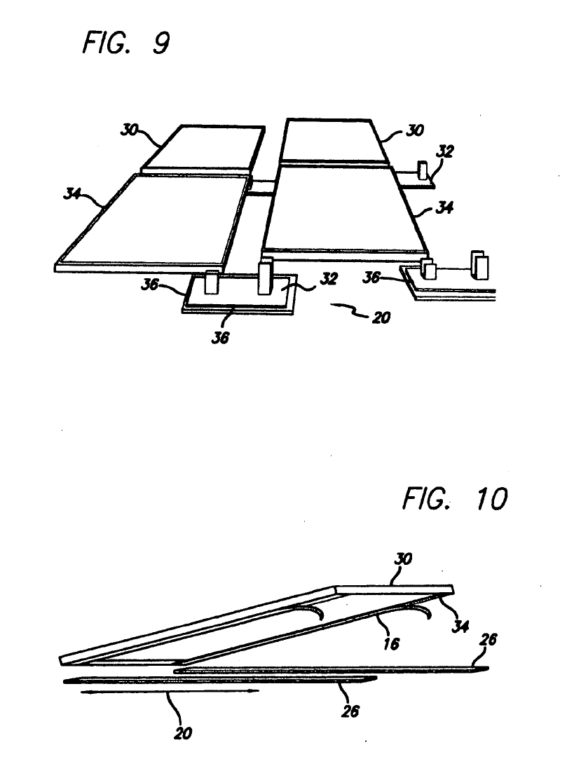

As mentioned above, in addition to thin film flexible solar panels, other commercially available solar panels are rigid and sold pre-framed. The attachment means and methods herein described can also be adapted for attachment of them to roof system surfaces 20 as well. Two such attachment methods are shown in FIGS. 9 and 10. In FIG. 9, the framed solar panels 30 can be attached at each corner to a suitable bracket 32 by any conventional means, such as bolts, or screws, or other adhesive (not shown). Although not shown in this embodiment, assuming there is sufficient contact area between the frame 34 of the panels 30 and the brackets 32 such that sufficient hook and loop material can be applied to achieve design goals in terms of resistance to uplift wind pressure on the installed panels (see detailed discussion below), it would also be possible to utilize hook and loop materials as the attachment means between the panels 30 and the brackets 32. The brackets 32 can be attached to the roof system surface 20 using the hook and loop method described above in which the hook material 14 is attached to the underside of the base 36 of the bracket 32. In this instance, it would be necessary that the total surface area of mated hook and loop materials 14 and 16 on all of the brackets 32 in the array of installed panels 30 such that the resultant resistance of the installed panel array to wind pressure uplift meets design goal. FIG. 10 shows how the framed panel 30 can be directly attached to the roof system surface 20 by applying strips 26 of the loop material 16 directly to the surface 20, and then mating thereto the hook material 14 which is attached to the frames 34. Because the frames 34 are typically constructed of some type of metal, the intermediate layer of adhesive tape 12 will be required.

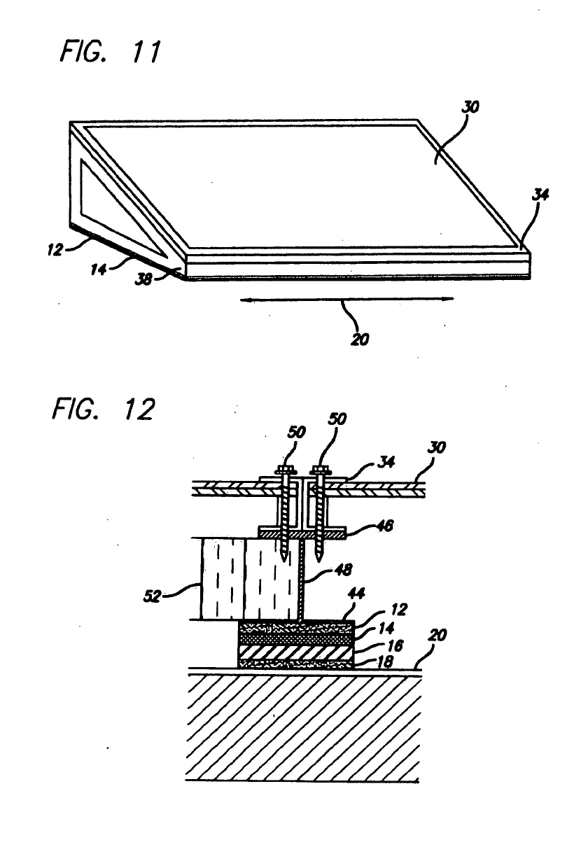

FIG. 11 shows another possible installation option using framed solar panels 30. In this arrangement, because of the geo-latitude of the installation site, it is preferred that the panels 30 be raised off of the horizontal (or whatever plane the exiting roof system surface 20 resides in). Therefore, the framed solar panels 30 are first attached to a substrate structure 38 that will, once attached to the roof system surface 20, place the panels in the proper elevation. In this instance, the hook material 14 can be attached to the base 40 of the structure 38, and then mated with the loop material 16 that is attached to the surface 20. Because the structure 38 will likely be made of metal of other similar material, the intermediate adhesive layer 12 will be utilized. It will again be necessary to ensure that the total amount of mated hook and loop materials 14 and 16 will be sufficient to obtain the design goal for resistance to wind pressure for the particular installation.

FIG. 12 depicts yet another way in which framed solar panels 30 can be attached to a roof system surface 20 using the hook and loop system. For some installations, it is preferred that, although the panels 30 can be laid parallel to the surface 20, that the panels 30 be elevated a short distance above the surface 20. There can be several reasons for this, one being the desire to install some type of additional insulation material between the panels 30 and the surface 20, or to provide space for other items, such as wires, cables or air conditioning tubes. In order to provide that space, spacer block or rail units 42 can be utilized, shown in cross-section in FIG. 12. In this embodiment, the units 42 can be made of any sufficient rigid and durable material, such as aluminum, and comprise a flat base 44 and an upper platform area 46, separated by a rib 48 that can be of any desired length. The frame portion 34 of the panels 30 are attached to the upper platform area 46 by any conventional means, such as the screws 50 depicted here. The base 44 is attached to the roof system surface 20 using the hook-and-loop sandwich described above, which, as depicted in FIG. 12 comprises adhesive layer 12, the hook material 14, the loop material 16, and another adhesive layer 18. Using the cross-sectional shape for unit 42 as shown in this Figure (which resembles and I-beam), allows for maximizing the base 44 and platform 46 surface areas while adding as little weight to the overall installation as possible. Also, this I-beam shape will also nicely accommodate the installation of insulation 52 in the space between the base 44 and platform 46.

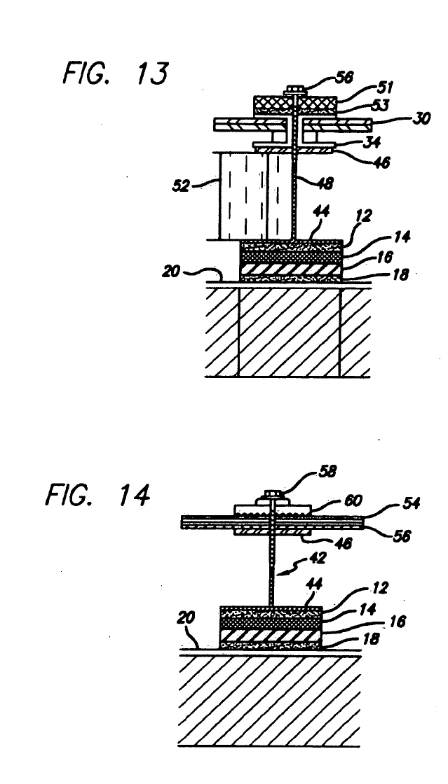

A slightly different embodiment is shown in FIG. 13 in which instead of a pair of screws 50, each of which punctures the framed panel 30 and frame 34, a single screw 56 and a pair of washers 51 and 53 are utilized, with washer 51 being made of metal, and washer 53 being made of a rubber material such as neoprene. In this embodiment, a single screw 50 is used to hold the washers 51 and 53 securely against the tops of the frames 34 of adjacent panels 30.

An alternative means for attaching either framed or unframed rigid solar panels is shown in FIG. 14, in which the solar panel 54 (which is shown here as a flexible panel, but which could also be a framed panel) is affixed to a backing plate 56. This Figure depicts un-framed solar panels 54 being attached to an I-Rail unit 42 by means of a single threaded screw 58 that holds bracket 60 in place against the adjoining panels 54 and plates 56 so they are held in position on the upper platform area 46 of the unit 42. Using this embodiment, it may not be necessary that the solar panels be adhered to the plate 56 (as shown in this Figure). In a suitable situation, the use of the brackets 60 may be sufficient to hold the panels in correct position against the plate 56. The attachment of the base 40 to the roof system surface 20 is as described above. This Figure also depict another way in which flexible thin film panels 10 can be attached in an elevated position above the roof surface 20.

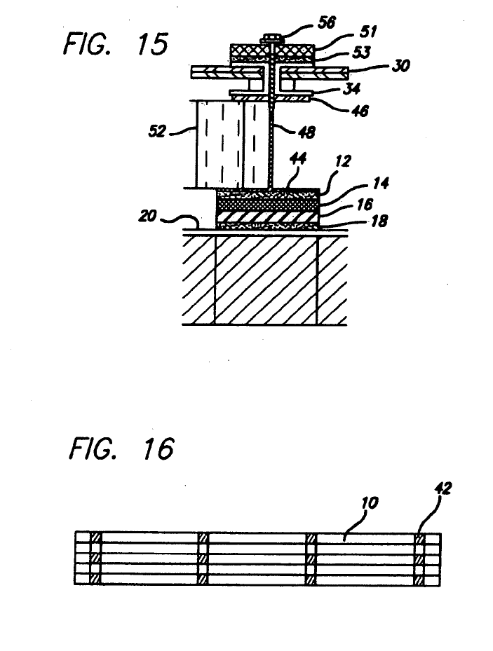

FIG. 15 depicts yet another embodiment for attaching the adjacent panels 54 to the I-Rails 42. As shown here, the backing plates 56 are designed and constructed to be slightly wider than the panels 54 so that each plate 56 will have a flange 57 that extends a short distance, and those adjacent flanges 57 will overlap on the upper platform of the I-Rail unit 42, to which they can be securely attached using a single screw 50.

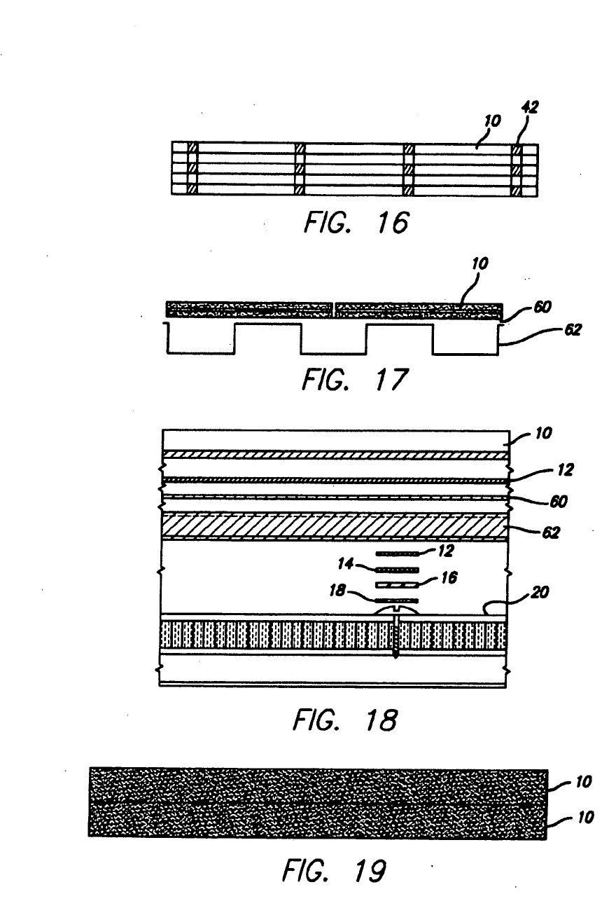

As mentioned above, the units 42 can be in the form of elongate rails or shorter blocks. In most instances, the shorter block configuration will be preferred so as to reduce cost. As with all other installations, however, it will be necessary to ensure that the coverage area of mated hook and loop material is sufficient to withstand the design wind pressure and uplift force on the installed panels. FIG. 16 depicts one such arrangement in which the block-shaped units 42 are arranged so as to hold the maximum number of panels with the minimum number of units 42.

FIG. 17 is another embodiment by which either the flexible or framed panels 54 can be attached to an underlying metal plate 60, but in this instance the underlying metal plate 60 is attached to another structure 62 which has a corrugated shape (shown in cross-section in this Figure). This type system can be used when the existing roof system surface 20 does not lend itself to adhesive attachment. For example, if the existing roof system surface 20 included a gravel material as the top most layer, applying adhesive directly to the gravel would not prove workable. Accordingly, in that instance a substrate such as the corrugated structure 62 shown in this Figure can be utilized. The panels 54 can be attached to the upper side of the metal plate 60 using either direct adhesive or the hook and loop system, and then the structure 62 attached to the roof surface by any suitable means, for example, cables or poles (not shown). This structure 62 can also be used for attachment to roof system surfaces that would also accommodate one of the direct attachment embodiments depicted above, but the addition of a continuous metal substrate is preferred. For example, it may be that the owner of the building wants to run wires, cables or other items under the panels, in which case each corrugated channel will also act as a raceway for holding and hiding the cable and wires. In this latter instance, the structure 62 can be attached to the roof system surface 20 using the hook and loop system described above, which is depicted in cross-section schematic in FIG. 18.

FIG. 19 depicts the relative length and width of a typical side-by-side arrangement of flexible panels 10.

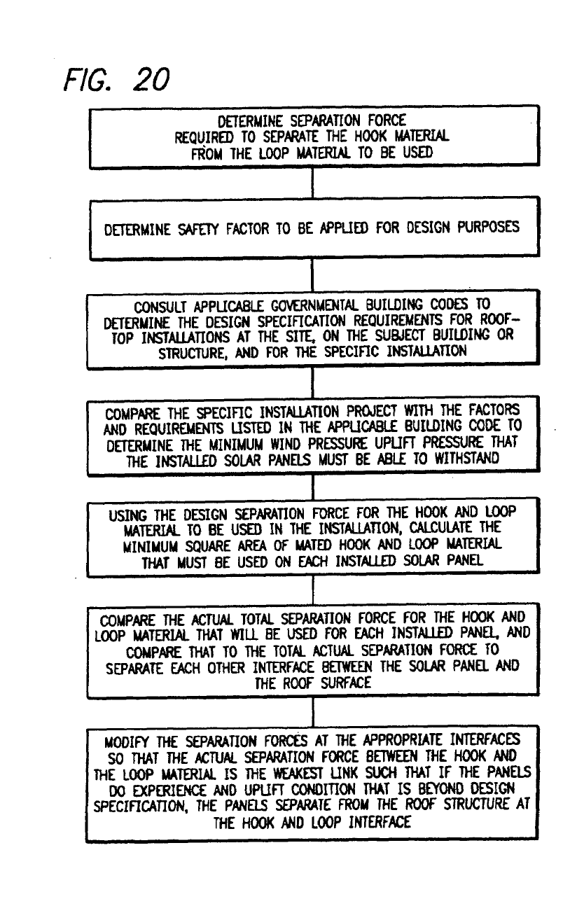

It is of course important that each and every installation being approached as a unique project that must be considered independently in terms of, among other things, the amount of mated hook and loop material 14 and 18 that must be applied. In this regard, the steps discussed below (and generally summarized in FIG. 20) must usually be undertaken for each installation project:
1. Determine actual force in pounds per square inch necessary to separate the hook material from the loop material of the hook and loop product to be used in the installation (“Fsa”) using standard testing protocols.
2. Determine desired design separation force (“Fsd”) that will be used in arriving at a suitable designed-in margin for error and safety, such as Fsa divided by 3.
3. Determine the actual geographic site location for the installation project (“the Site”).
4. Consult the applicable governmental building code for the Site (for example, the California Building Code for most locations within the state of California), and determine therefrom the design specification wind speed for that specific site location (typically given in the minimum miles per hour the building structure must be designed to withstand, such as 75 miles per hour)
5. Consult the applicable governmental building code for the Site and determine the criteria for categorizing the Site's “Exposure” (usually on a scale of A, B, C, or D) which is generally a measure of the Site's exposure to wind pressure due to surrounding topographic details.
6. Analyze the Site and its surrounding topographic details and apply against the Exposure criteria for that Site to determine the Site's Exposure grade.
7. Consult the applicable governmental building code for the Site to determine the criteria for any other factors that have to be taken into account when calculating the minimum uplift force which the installed panels must be designed to withstand. Such other factors typically include the height of the structure, the “importance” of the facility, the slope of the roof to which the panels will be attached, whether the roof has overhang or other distinguishing features, and where on the roof the panels will be installed (near the edge of the roof, for example).
8. Compare and apply any such other factors to the specific structure and the specific installation to determine any other multipliers that have to be taken in to account in the calculation of the amount of mated hook and loop material to be used for each installed panel.
9. Take all of the applicable factors into account to determine the minimum uplift force (“Fmu”) in pounds per square inch that the specific roof installation on that specific structure and type roof at that Site must be designed to withstand.
10. Determine the total square area of coverage for each of the solar panels to be installed in square inches. For example, a solar panel that is 216 inches long and 15.5 inches wide will have a total coverage area of 3348 square inches.
11. Multiply the Fmu (in pounds per square inch as calculated in steps 1-9 above) times the total area of each individual solar panel to be installed using the hook and loop attachment to calculate total uplift pressure which each installed panel must be able to withstand. For example, if Fmu for a particular project was 0.14, and Fsa was 9 pounds per square inch, such that Fsd is 3 pounds per square inch, then the total area on each installed panel that must have mating hook and loop material is 15.6.24 square inches.
12. Design all other interfaces in the attachment of the solar panels to the roof system surface to have an Fsa that is greater than that for the applied hook and loop material, so that in the unlikely event the solar panels are subjected to wind pressure and uplift that is greater than the designed for capacity, the panels will separate from the roof at the hook and loop interface so as to minimize damage to the roof and the building structure.
13. Coordinate with the manufacturer of the existing roof system surface to ensure that application of the panels will not adversely affect the surface or hinder or void any existing warranty on the structure integrity and weather resistance of the roof system surface.

A sample spreadsheet showing a table of the calculation performed for a different type structures in an area rated for wind pressure of 75 miles per hour, and a grade “C” exposure, is set forth here (references to Figures, Tables and Sections are to those referenced items in the California Building Code, and references to “Velcro” are references to Velcro® hook and loop product, and specifically to Velco® hook model 752 and loop model 3001:

| | | | | Ce: | | | | | |
|---|---|---|---|---|---|---|---|---|---|
| | | | | 1.06 | 1.13 | 1.19 | 1.23 | 1.31 | 1.43 |
| | Description | Cq | | 0-15 | 20 | 25 | 30 | 40 | 60 |
| ELEMENTS & | ROOF ELEMENTS (Not partially enclosed) | | | | | | | | |
| COMPONENTS | slope < 7:12 | 1.3 | out | 20.0 | 21.3 | 22.4 | 23.2 | 24.7 | 27.0 |
| NOT IN AREAS OF | P × 1′-4″ × 18′-0″ lbs | | | 478 | 509.9 | 537 | 555.1 | 591 | 645.3 |
| DISCONTINUITY | Area of Velcro (3 psi allow) in² | | | 150 | 170 | 180 | 188 | 198 | 216 |
| | slope 7:12 to 12:12 | 1.3 | in/out | 20.0 | 21.3 | 22.4 | 23.2 | 24.7 | 27.0 |
| | P × 1′-4″ × 18′-0″ lbs | | | 478 | 509.9 | 537 | 555.1 | 591 | 645.3 |
| | Area of Velcro (3 psi allow), in² | | | 160 | 170 | 180 | 186 | 198 | 216 |
| | slope > 12:12 | 1.2 | in/out | 18.4 | 19.7 | 20.7 | 21.4 | 22.8 | 24.9 |
| | P × 1′-4″ × 18′-0″ lbs | | | 442 | 470.7 | 495.7 | 512.4 | 546 | 595.7 |
| | Area of Velcro (3 psi allow), in² | | | 148 | 157 | 166 | 171 | 182 | 199 |
| | PARTIALLY ENCLOSED STRUCTURES | | | | | | | | |
| | slope < 2:12 | 1.7 | out | 26.1 | 27.9 | 29.3 | 30.3 | 32.3 | 35.2 |
| | P × 1′-4″ × 18′-0″ lbs | | | 626 | 666.8 | 702.2 | 725.8 | 773 | 843.9 |
| | Area of Velcro (3 psi allow), in² | | | 209 | 223 | 235 | 242 | 258 | 282 |
| | slope 2:12 to 7:12 | 1.6 | out | 24.6 | 26.2 | 27.6 | 28.5 | 30.4 | 33.2 |
| | P × 1′-4″ × 18′-0″ lbs | | | 589 | 627.6 | 660.9 | 683.2 | 728 | 794.2 |
| | Area of Velcro (3 psi allow), in² | | | 197 | 210 | 221 | 228 | 243 | 265 |
| | slope 2:12 to 7:12 | 0.8 | in | 12.3 | 13.1 | 13.8 | 14.3 | 15.2 | 16.6 |
| | P × 1′-4″ × 18′-0″ lbs | | | 294 | 313.8 | 330.5 | 341.6 | 364 | 397.1 |
| | Area of Velcro (3 psi allow), in² | | | 99 | 105 | 111 | 114 | 122 | 133 |
| | slope > 7:12 to 12:12 | 1.7 | in/out | 26.1 | 27.9 | 29.3 | 30.3 | 32.3 | 35.2 |
| | P × 1′-4″ × 18′-0″ lbs | | | 626 | 666.8 | 702.2 | 725.8 | 773 | 843.9 |
| | Area of Velcro (3 psi allow), in² | | | 209 | 223 | 235 | 242 | 258 | 282 |
| | slope > 12:12 | 1.6 | out | 24.6 | 26.2 | 27.6 | 28.5 | 30.4 | 33.2 |
| | P × 1′-4″ × 18′-0″ lbs | | | 589 | 627.6 | 660.9 | 683.2 | 728 | 794.2 |
| | Area of Velcro (3 psi allow), in² | | | 187 | 210 | 221 | 228 | 243 | 265 |
| | slope > 12:12 | 1.2 | in | 18.4 | 19.7 | 20.7 | 21.4 | 22.8 | 24.9 |
| | P × 1′-4″ × 18′-0″ lbs | | | 442 | 470.7 | 495.7 | 512.4 | 546 | 595.7 |
| | Area of Velcro (3 psi allow), in² | | | 148 | 157 | 166 | 171 | 182 | 199 |
| ELEMENTS & | ROOF EAVES, RAKES OR RIDGES ON RIDGES WITHOUT OVERHANGS^{11, 12} | | | | | | | | |
| COMPONENTS | slope < 2:12 | 2.3 | up | 35.4 | 37.7 | 39.7 | 41.0 | 43.7 | 47.7 |
| IN AREAS OF | P × 1′-4″ × 18′-0″ lbs | | | 846 | 902.2 | 950.1 | 982 | 1046 | 1142 |
| DISCONTINUITIES | Area of Velcro (3 psi allow) in² | | | 283 | 301 | 317 | 328 | 349 | 381 |
| ^{2, 3, 4} | | | | | | | | | |

Basic Wind Speed: 75 mph (FIG. 16-1)
qs = 14.5 psf (Table 16-F)
Exposure: C (Section 1616)
Occupancy: 4 (Table 16-K)
lw = 1.00 (Table 16-K)
P = CeCqqslw

It has also be discovered that either the hook or the loop material can be added to certain membrane type roofing materials during the construction process by which the membrane type roofing material is produced. These membrane materials are typically used to finish a roofing system, being the final or top layer of the typical roof system installation before the placement of solar panels. These typical membranes are manufactured in strips that are then transported to the roof construction site, and are applied to the roof structure to create the water- and weather-proof top layer of the roofing system. For example, one type of roof structure may have metal or other material as to the upper construction material. In finishing the roof system, a layer of insulation might be added to the top of the upper construction material and fixedly attached by means of screws that screw into the upper construction material. On top of the insulation, additional layers of primer or other adhesive material may be applied as a coating, and then the strips of membrane material applied to that coating. The strips of membrane material are typically laid down side-by-side and end-to-end, with a small area of overlap at each junction. The overlap areas are typically adhered together by either adhesives or by a heat welding process in which the overlap areas are locally heated to return the membrane material in that region to a sufficiently molten state that the overlapped areas will meld and bond upon cooling, creating a seamless, strong upper roof surface.

There are many different types of membrane roofing materials, but one common type utilizes a build-up process of construction in which a first layer of material, such as a fiberglass mesh, is laid down and then which are added layers of a liquid or liquids that sufficiently harden upon cooling to provide the desired finished product. In the construction process for such membranes, it is possible to add either the hook or loop material to the membrane during the final stages of manufacture such that the membrane that is then delivered to the job site is already fitted with the hook or loop material, thus avoiding the step in the field of attaching the hook or loop material to the membrane after it is installed on the roof (as was described above).

As discussed above, it is preferred to attach the less expansive hook material to the underside of the solar panels, so that the entire underside can have hook material at a lower cost than would be possible if the entire underside were covered with loop material. Therefore, it is preferred that only strips of the loop material be attached to the membrane.

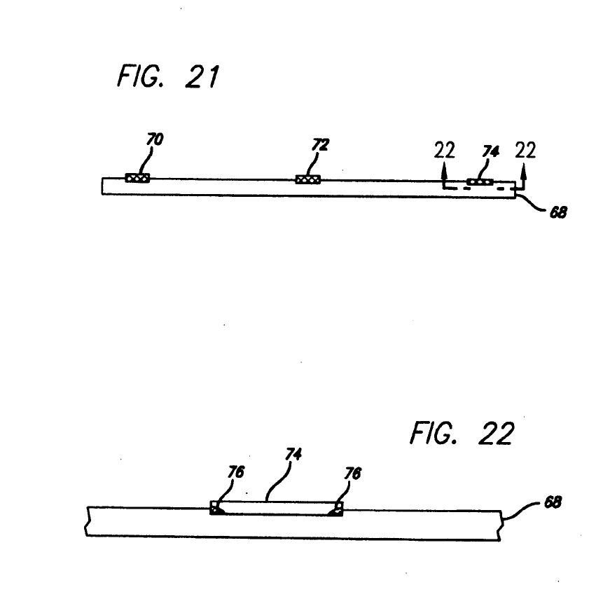

Looking at FIG. 21, a built-up membrane 68 is shown in cross section having strips 70, 72 and 74 of loop material embedded and thus integrally attached to the upper layer of the membrane 68. As shown in this FIG. 21 and in more detail in FIG. 22, the preferred attachment process will involve embedding the strips directly into the upper layer of the membrane 68 during the manufacturing process. While there may be sufficient adhesion between the membrane 68 and the strips 70, 72 and 74 without having this embedded feature, by including a mechanical lock between the membrane 68 and the strips 70, 72 and 74 a more reliable attachment is achieved, and is thus preferred. Therefore, during the construction process for the membrane 68, it is preferred that the strips 70, 72 and 74 be laid onto the membrane 68 after the penultimate layer of material has been applied, and while that layer is not yet fully hardened and thus still at least “tacky” so that there is an initial attachment, and that the final layer of membrane material be added thereafter, with a portion 76 of the liquid membrane material seeping or being forced into the sides of the strips 70, 72 and 74 (as best seen in FIG. 22). This will provide for a stronger attachment bond between the membrane 68 and strips 70, 72 and 74. It will understood by those skilled in the art, however, that the amount of liquid membrane material should not be so great as to compromise the eventual attachment between the embedded loop material in the strips 70, 72 and 74 and the hook material on the bottom of the solar panels that will be attached thereto. It will also be understood by those skilled in the art that embedding the strips 70, 72 and 74 directly into the top layer of the membrane 68 is only one of other ways that the hook or loop material can be added to the membrane during its construction. For example, the hook or loop material could be added after the top layer of membrane material has be added, using a conventional adhesive such as those mentioned above.

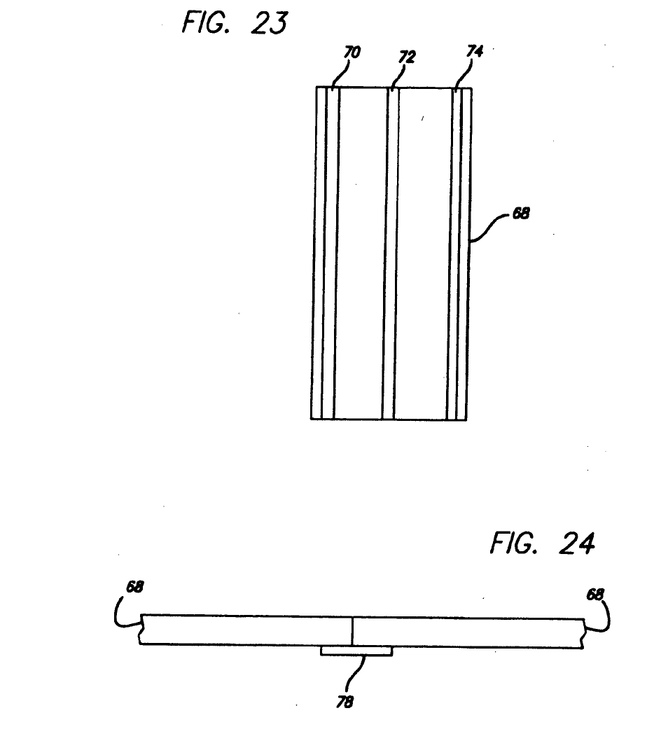

Looking at FIG. 23, it is seen that in the preferred embodiment, three strips 70, 72 and 74 are embedded in each membrane 68, and each of the strips 70, 72 and 74 extend the entire length of the membrane 68. Because, as mentioned above, the typical way to attach adjacent membrane pieces on the roof structure is to overlap them and then heal-weld them together, the outside strips 70 and 74 cannot be adjacent the very edge of the membrane 68. It is expected that leaving approximately two inches gap will provide for sufficient overlap material without subjecting the embedded strips to possible damage during the heat weld process.

Also, because it is intended that the membranes 68 with embedded strips 70, 72 and 74 will usable for most jobs, it will be required that the amount of loop surface area provided by the strips 70, 72 and 74 be sufficient for the vast majority of jobs (as determined by the method described above) so that the cross-sectional area of hook and loop attachment after the solar panels are installed to meet or exceed design specifications. Therefore, it is preferred that each membrane 68 will have the three strips 70, 72 and 74, and that each strip will be approximately 2 inches wide, evenly spaced and approximate 11 to 12 inches between the middle strip 72 and the two outer strips 70 and 74, on the typical membrane that is approximately one meter in width. If the width of the manufactured membrane 68 is material more or less wide than one meter, the width of the strips will have to be adjusted accordingly.

As shown in FIG. 24, the end-to-end attachment of the membranes 68 can be accomplished using an underpiece 68 (similar to that used in some carpet seam applications) so that the loop material in the ends of the strips 70, 72 and 74 is not damages when the membranes 68 are attached end to end.

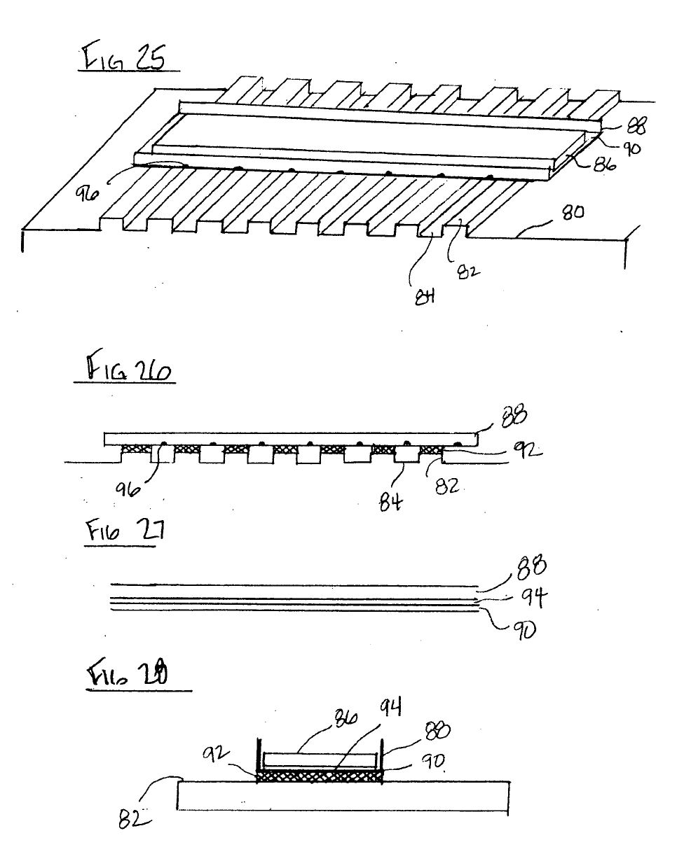

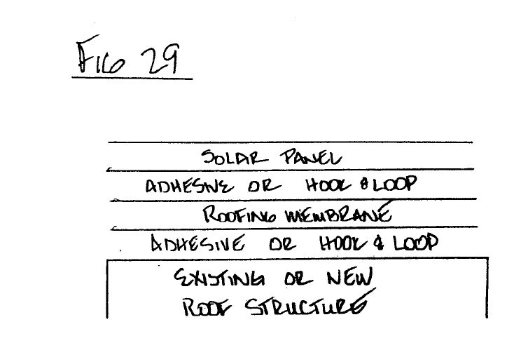

Another embodiment is shown in FIG. 25, for certain types of roofing materials, utilizing an intermediate tray-like structure will be most effective. As shown here, an upper roof material 80 is constructed of a corrugated metal, that is defined by repeating peaks 82 and valleys 84. The dimensions of such peaks and valleys can vary, with 1.5 to 3 inches deep and 2 to 12 inch spacing being common. In this embodiment, the flexible solar panel 86 is first attached to a tray-like structure 88. Tray 88 is preferrably constructed of 26-gauge galvanized metal, but many other materials could be used, including non-metallic materials such as plastic. In this embodiment, the panel 86 is attached to the upper surface 90 of the tray bottom by any suitable means, which could include adhesive or hook and loop material. As shown in FIG. 26 (side view), the tray 88 is attached via hook and loop material 92 where each of the peaks 82 comes into contact with the bottom of tray 88. The attachment between the solar panel 86 and the tray 88 is schematically shown in FIG. 27, where the panel 86 is attached to the tray bottom 90 by either adhesive or hook and loop material. In addition, in this embodiment, the solar panel could be mechanically attached to the bottom of the tray using screws or the like. If an adhesive (such as SikaLastomer®-68 ethylene propylene copolymer tape or similar) is used, the preferably hook and loop material is used for the tray-to-roof interface 92. It does not matter whether the hook or loop material is attached to the underside of the tray 88, or vice versa. Whereever the hook or loop material is attached, if the material used does not have peel-and-stick backing, then a commercial grade adhesive such as SikaLastomerg-68 ethylene propylene copolymer tape should be used. Regardless of what means of attachment are utilized, the resultant up wind force resistance must meet minimum design criteria. In the preferred embodiment, the interior tray has a width of at least 16 inches, is 18 feet long, and has a 1.5 inch lip so that a standard solar panel fits inside easily. The tray 88 may be equipped with drain holes 96 along its length to ensure that accumulated water is allowed egress promptly and effectively.

FIG. 28 shows an end view, in which the underside of the tray 88 is attached to one of the roof peaks 82 by hook and loop material 92. As shown here, the hook and loop material 92 extends the entire width of the tray 88. This may or may not be necessary depending on the amount of hook and loop material that is required after the calculations above are performed. Typically, pull off strength in excess of 3 psi is sufficient.

FIG. 29 is a schematic that shows how for certain roof structures to which a typical roofing membrane is to be attached, the solar panel can be first adhered to the upper surface of the membrane by either hook and loop or adhesive. The panel/membrane assemblage can then be directly attached to the roof surface. For example and not limitation, this embodiment can be used with built-up roofs, EPDM, TPO, modified asphalt, PVC, and metal roofing surfaces. The membranes to which the panels are preferrably attached are constructed of PVC, EPDM or TPO, as these material are considered in the industry to be effective for waterproofing existing roof systems and will not over time themselves become inherently adhered to the roof structure. Of course, whatever type of membrane is selected, it must first be determined that it is compatible with the existing roof material.

Although various specific embodiments have been set forth above, it will be clear to those skilled in the art that the inventive concepts herein disclosed are not limited to those specific embodiments. Accordingly, the scope of the protection herein provided is not limited to the specific embodiments, but is of the full scope of the following claims, including equivalents thereto.

What is claimed is:

1. An apparatus for attaching a flexible solar panel to a roof system surface, comprising:
a. a flexible solar panel having a defined length and width, thus having a calculated total surface area;
b. hook and loop attachment material for attaching said panel to said roof system surface;
c. the hook portion of said hook and loop material being attached to the underside of said panel or to said roof system surface,
c. the loop portion of said hook and loop material attached to the other of said roof system surface or said panel;
d. such that there is mating contact between said hook portion and said loop portion when said panel is placed into its desired position on the said roof system surface; and
e. the area of said mating contact is pre-determined to ensure sufficient separation force will be required to cause said panel to separate from said roof system surface at the interface between said hook portion and said loop portion.

2. The invention of claim 1 in which said hook portion is attached to the underside of said panel, and said loop portion is attached to said roof system surface.

3. The invention of claim 1 in which said hook portion and said loop portions are attached to said panel and said roof system surface respectively by a separately applied adhesive material such as double-sided adhesive tape.

4. The invention of claim 1 in which said hook portion or said loop portion that is attached to the underside of said panel covers the entirety of the underside of said panel.

5. The invention of claim 4 in which said hook portion or said loop portion that is attached to the underside of said panel is directly attached.

6. The invention of claim 5 in which said roof system surfaces comprises a plurality of membranes in which said hook portion or said loop portion has been attached during the process by which the membrane is manufactured.

7. The invention of claim 6 in which said hook portion or said loop portion has been attached by embedding into the upper layer of said membrane.

8. The invention of claim 7 in which said hook portion or said loop portion comprise strips.

9. The invention of claim 8 in which each said membrane is approximately one meter in width, and there are at least three strips of hook or loop, each strip being approximately two inches wide.

10. The invention of claim 1 further comprising an intermediate structure having a first side and a second side that is attached at said first side to said roof system surface, extends a distance thereabove, and to said second side thereof is attached said panel, in which the attachment means for attached said first side and said second side to said roof system surface and the underside of said panel respectively comprises hook and loop material.

11. The invention of claim 10 in which said intermediate structure is constructed of aluminum and has an I-beam cross sectional configuration.

12. The invention of claim 10 in which said intermediate structure has a corrugated cross sectional configuration that substantially extends the entire length and width of said panel.

13. A method for attaching solar panels having a defined length and width to a roof system surface of a building using hook and loop material, the method comprising the steps:
a. determining the actual total separation force per square inch of said hook and loop material;
b. determining the safety factor to used as a multiplier as to the actual separation force for margin-of-error design purposes;
c. consulting the applicable building codes for the building location, type and surrounding topography, and for the location of the installed panels on the roof to determine design factors to be taken into consideration for the minimum allowable wind pressure and uplift force to be withstood by the installed panels before separating for the roof system surface;
d. applying said factors to the intended application to determine the minimum amount of mated hook and loop material that must be used on each attached panel;
e. comparing the actual separation force required to separate the attached panels from the roof system surface at the hook and loop interface;
f. determining the actual separation force required to separate the attached solar panels from the roof system surface at each of intermediate interface; and
g. if necessary, modifying the interfaces so that any separation due to wind pressure and uplift forces on the attached panels will occur at the hook and loop interface.

14. A method of embedding hook or loop strips into the upper layer or a membrane roofing material constructed of multiple layers, said method comprising the steps of attaching said strips to the penultimate layer of said membrane, and then adding a final layer such that a portion of the final layer forms a mechanical bond with the strip without compromising the ability of the hook or loop material to form a bond with respectively mated hook or loop material.

15. A method of attaching solar panels to a corrugated upper roof material having peaks and valleys, with the peaks presenting a flat upper surface, the method comprising:
a. adhering the solar panel to an appropriately sized tray using mechanical or adhesive means;
b. adhering one of mating hook and loop materials to the underside of the tray;
c. adhering the other of the mating hook and loop materials to the upper flat surface of the peaks of the corrugated roof material; and
d. ensuring that the resultant pull-off force is sufficient to meet design criteria.

16. A method of attaching solar panels to a substantially flat upper roof material surface, the method comprising:
a. adhering the solar panel to a roof membrane material that is intended for attachment to and is compatible with said upper roof material surface;
b. adhering one of mating hook and loop materials to the underside of said membrane;
c. adhering the other of the mating hook and loop materials to the upper flat surface of the roof; and
d. ensuring that the resultant pull-off force is sufficient to meet design criteria.
